(19) United States
(12) Patent Application Publication
(10) Pub. No.: US 2025/0079163 A1
(43) Pub. Date: Mar. 6, 2025

(54) SEMICONDUCTOR DEVICE AND METHOD OF MANUFACTURING SEMICONDUCTOR DEVICE

(71) Applicant: SK hynix Inc., Icheon-si Gyeonggi-do (KR)

(72) Inventor: Sung Kun PARK, Icheon-si Gyeonggi-do (KR)

(73) Assignee: SK hynix Inc., Icheon-si Gyeonggi-do (KR)

(21) Appl. No.: 18/396,365

(22) Filed: Dec. 26, 2023

(30) Foreign Application Priority Data
Aug. 29, 2023 (KR) 10-2023-0113340

(51) Int. Cl. H01L 21/02; H01L 21/304; H01L 21/8234

(52) U.S. Cl. CPC H01L 21/02362; H01L 21/02304; H01L 21/304; H10D 84/0128; H10D 84/038

(57) ABSTRACT

A method of manufacturing a semiconductor device may include forming a polishing stop layer on a substrate, forming a stack on the polishing stop layer, forming channel structures extending through the stack and the polishing stop layer and having different heights, polishing the substrate and the channel structures to expose the polishing stop layer, and removing the polishing stop layer.

### CROSS-REFERENCE TO RELATED APPLICATION

This application claims priority under 35 U.S.C. § 119 (a) to Korean Patent Application No. 10-2023-0113340 filed on Aug. 29, 2023, in the Korean Intellectual Property Office, which is incorporated herein by reference in its entirety.

### BACKGROUND

### 1. Technical Field

The present disclosure relates to an electronic device and a method of manufacturing the electronic device. More particularly, this disclosure relates to a semiconductor memory device and a method of manufacturing the semiconductor memory device.

### 2. Related Art

Semiconductor memory integration density is mainly determined by the area occupied by a memory cell. As semiconductor memory integration density has increased the amount of memory that can be formed on a single layer has reached a limit. A three-dimensional semiconductor memory device in which memory cells are stacked on top of each other on a substrate has been proposed. Structures and manufacturing methods are being developed to improve the operational reliability of three-dimension semiconductor memory device.

### SUMMARY

According to an embodiment of the present disclosure, a method of manufacturing a semiconductor device may include forming a polishing stop layer on a substrate, forming a stack on the polishing stop layer, forming channel structures that extend through the stack and the polishing stop layer into the substrate, at least two channel structures among the channel structures have different heights. The method includes polishing the substrate and the channel structures to expose the polishing stop layer then and removing the polishing stop layer.

According to an embodiment of the present disclosure, a method of manufacturing a semiconductor device may include forming a substrate including a first region and a second region, forming a polishing stop layer having stress of a first type in the first region of the substrate, forming a gap fill layer having stress of a second type different from the first type in the second region of the substrate, forming a stack on the polishing stop layer and the gap fill layer, forming channel structures extending through the stack and the polishing stop layer and having different heights, and polishing the substrate and the channel structures to expose the polishing stop layer.

According to an embodiment of the present disclosure, a method of manufacturing a semiconductor device may include forming a buffer layer, forming a polishing stop layer on the buffer layer, forming a stack on the polishing stop layer, forming channel structures extending into the buffer layer through the stack and the polishing stop layer, polishing the buffer layer and the channel structures to expose the polishing stop layer, and removing the polishing stop layer.

### BRIEF DESCRIPTION OF THE DRAWINGS

FIGS. 1A and 1B are diagrams illustrating a semiconductor device according to an embodiment of the present disclosure.

FIGS. 2A to 2C are diagrams illustrating a method of manufacturing a semiconductor device according to an embodiment of the present disclosure.

FIGS. 3A to 3D are diagrams illustrating a method of manufacturing a semiconductor device according to an embodiment of the present disclosure.

### DETAILED DESCRIPTION

An embodiment of the present disclosure provides a semiconductor device and a method of manufacturing the semiconductor device having a stable structure and improved characteristic.

According to the present technology, a semiconductor device having a stable structure and improved characteristic may be provided.

According to the present technology, because channel structures may be formed to have substantially the same height, memory cells may have a uniform characteristic in a subsequent process.

Hereinafter, embodiments according to the technical spirit of the present disclosure are described with reference to the accompanying drawings.

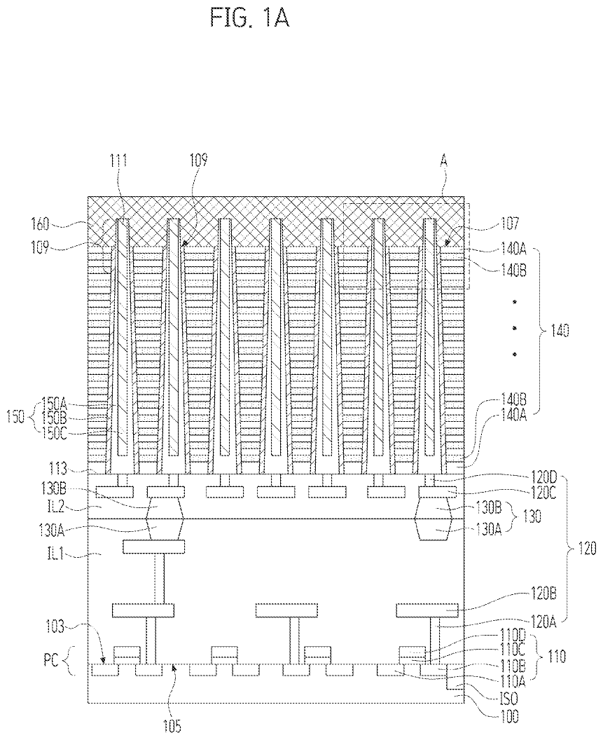

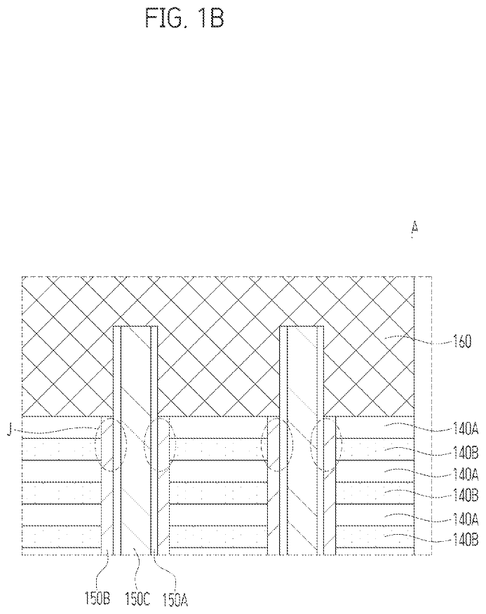

FIGS. 1A and 1B are vertical cross-sectional diagrams illustrating a semiconductor device according to an embodiment of the present disclosure. FIG. 1B is an A enlargement of a section of the structure shown in the upper right-hand corner of FIG. 1A, said section being enclosed within a square formed of broken line identified by reference letter “A.”

Referring to FIGS. 1A and 1B, the semiconductor device may include a substrate 100, a gate structure 140, channel structures 150, and a source structure 160. The semiconductor device may further include at least one of an isolation insulating layer ISO, a peripheral circuit PC, an interconnection structure 120, a bonding structure 130, a first interlayer insulating layer IL1, and a second interlayer insulating layer IL2.

The substrate 100, which is semiconductor material, may be a silicon wafer, a SiGe wafer, or an SOI wafer. Components of the peripheral circuit PC may be formed and positioned on the top surface 103 of substrate 100 and the bottom surface 105 of the first interlayer insulating layer IL1. The isolation insulating layer ISO may also be formed and positioned in the substrate 100. An active region of the substrate 100 may be defined by the isolation insulating layer ISO.

The peripheral circuit PC components may include a transistor 110, a capacitor (not shown) and/or a resistor (not shown). For example, the transistor 110 may include a first junction 110A, a second junction 110B, a gate insulating layer 110C, or a gate electrode 110D. The gate insulating layer 110C may be positioned between the gate electrode 110D and the substrate 100. The gate insulating layer 110C and the isolation insulating layer ISO may include an insulating material such as oxide or nitride.

The interconnection structure 120 may be positioned on the substrate 100. Here, the interconnection structure 120 may include vertical first contact vias 120A, which are electrically and mechanically connected to horizontal first lines 120B. The interconnection structure may also include horizontal second lines 120C, which are electrically and mechanically connected to vertical second contact vias 120D.

The first contact vias 120A and the first lines 120B may be formed and located in the first interlayer insulating layer IL1. The first interlayer insulating layer IL1 may be positioned on the substrate 100. At least one of the vertically-oriented first contact vias 120A may be connected to the transistor 110. At least one of the horizontally-oriented first lines 120B may be connected to the first contact via 120A connected to the transistor 110.

The gate structure 140 may be positioned on the peripheral circuit PC. The gate structure 140 may include alternately stacked insulating layers 140A and conductive layers 140B.

The insulating layers 140A may be formed of an insulating material such as a metal oxide. The conductive layers 140B may be formed of a conductive material such as tungsten, molybdenum, or polysilicon. The conductive layers 140B may embody a word line, a bit line, a drain select line, as well as a source select line.

As shown in FIGS. 1A and 1B, the source structure 160 may be positioned on the gate structure 140. The channel structures 150 may extend completely through the gate structure 140 and part way into the source structure 160. The top end of the gate structure may thus be connected to the source structure 160.

The channel structures 150 are tapered. The channel structures 150 may thus have horizontal cross-sections, which get increasingly narrow as the vertical distance from the second interlayer insulating layer IL2 increases. Stated another way, each channel structure 150 has an upper portion, the width of which is narrower than the width of a lower portion below the upper portion.

Each channel structure 150 may include at least a channel layer 150A, a memory layer 150B surrounding the channel layer 150A, and an insulating core 150C inside the channel layer 150A. The channel layer 150A may be electrically and mechanically connected to the source structure 160.

When channel structures 150 have different heights, which may be due to a manufacturing process, the heights of the channel structures 150 protruding above the upper or top surface 107 of the gate structure 140 may be different. Accordingly, the locations of electrical junctions formed in the channel structures 150 may be different as a result of a manufacturing process.

According to an embodiment of the present disclosure, heights H of the channel structures 150 may be made equalized, i.e., the heights of multiple channel structures 150 may be made the same or at least substantially the same by polishing the upper surfaces or top ends 109 the channel structures 150 that are too high. In other words, the channel structures 150 may be polished so that an upper surface 109 of the channel layer 150A and an upper surface 111 of the insulating core 150C of the channel structures 150 are co-located or positioned at substantially the same vertical level above the top surface 113 of the second interlayer insulating layer IL2. Accordingly, the channel structures 150 may include the junctions J, best seen in FIG. 1B, positioned at substantially the same level above the top surface 113 of the second interlayer insulating layer IL2. Here, the junction J may be positioned in the channel layer 150A of each of the channel structures 150. The junction J may refer to a region doped with an impurity in the channel layer 150A. According to the present disclosure, because the junctions J of the channel structures 150 may be positioned at substantially the same level, memory cells may have better and more uniform operating characteristics.

As used herein, the term “polish” refers to any process that flattens a surface, i.e., polishing removes surface irregularities. Polishing is often done by abrasion. Abrasion is the wearing, grinding, or rubbing away of material by friction.

An upper end (or upper surface) of the memory layer 150B may be located below or lower than the upper end (or upper surface) of the channel layer 150A and below or lower than the upper end (or upper surface of the insulating core 150C. This is because a portion of the memory layer 150B may need to be removed to form the junction J in the channel layer 150A located at a level corresponding to the conductive layers 150B during the manufacturing process. The conductive layers 150B of channel structures 150 may be a source select line.

Still referring to FIG. 1A, the second lines 120C and the second contact vias 120D of the interconnection structure 120 may be positioned under the gate structure 140. The second contact vias 120D may be connected to the channel structures 150, respectively. The second lines 120C may be positioned under the second contact vias 120D. The second lines 120C may be connected to the second contact vias 120D, respectively. The second contact vias 120D and the second lines 120C may be positioned in the second interlayer insulating layer IL2.

The bonding structure 130 may be positioned between the gate structure 140 and the peripheral circuit PC. The bonding structure 130 may include first bonding pads 130A and second bonding pads 130B. The first bonding pads 130A may be positioned in the first interlayer insulating layer IL1, and the second bonding pads 130B may be positioned in the second interlayer insulating layer IL2. In FIG. 1A, the left side of the first interlayer insulating layer IL1 shows that a first bonding pad 130A may be connected to one of the first lines 120B. A second bonding pad 130B may be connected to one of the second lines 120C. The first bonding pads 130A and the second bonding pads 130B may be bonded to each other.

According to the structure as described above, the channel structures 150 may have the same height or substantially the same height. The junctions J formed in the channel layer 150A of the channel structures 150 may therefore be positioned at the same level or at substantially the same level.

A structure comprised of a memory cell array including channel structures 150 and a peripheral circuit PC related to or that requires the memory cell array may be formed or manufactured as separate structures and bonded together. Accordingly, by configuring the peripheral circuit PC related to the operation of the memory cell array as a separate structure, more memory cells may be formed in the memory cell array allowing for more data to be stored in a larger-capacity memory cell array.

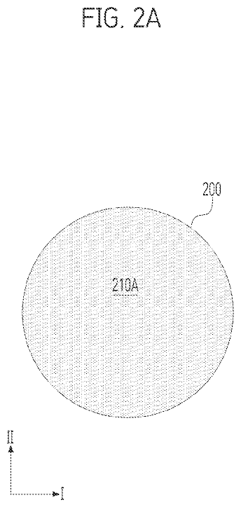

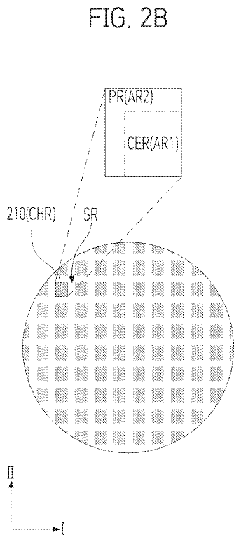

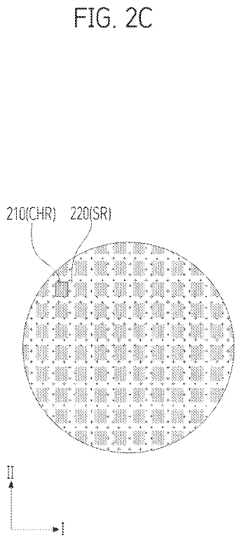

FIGS. 2A to 2C are diagrams illustrating a method of manufacturing a semiconductor device according to an embodiment of the present disclosure. Hereinafter, a content overlapping a content described above is omitted.

Referring to FIG. 2A, which is a top view, a preliminary polishing stop layer 210A may be formed on a substrate 200, not visible in FIG. 2A. The preliminary polishing stop layer 210A may be formed to cover at least the top surface (not visible) of the substrate 200.

The preliminary polishing stop layer 210A may be a material having an etching selectivity to oxide. Alternatively, the preliminary polishing stop layer 210A may be one of nitride, tungsten, cobalt silicide, aluminum oxide, and titanium silicide.

As used herein, the term “chip” refers to a small piece of semiconductor material that forms the base of an integrated circuit. Several identical chips may be fabricated in a single wafer. After their fabrication, multiple individual chips may by cutting or dicing them from a wafer using scribe lane regions.

Referring to FIG. 2B, the substrate 200 may include a chip region CHR and a scribe lane region SR. The chip regions CHR may be regions in which semiconductor chips are formed. The semiconductor chips may be repeatedly formed on the substrate 200, and the chip regions CHR may be arranged in a first direction I and a second direction II crossing the first direction I. The scribe lane region SR may be positioned between the chip regions CHR. The scribe lane region SR may be a portion cut out in a dicing process for separating the semiconductor chips. The chip regions CHR may be separated from each other by cutting the substrate 200 along the scribe lane region SR.

The chip regions CHR may include a first region AR1 and a second region AR2. However, the present disclosure is not limited thereto, and the second regions AR2 of the chip regions CHR may partially overlap the scribe lane region SR. Here, the first region AR1 may be a cell region CER, and the second region AR2 may be a peripheral circuit region PR. The peripheral circuit region PR may surround the cell region CER. The cell region CER may be a region where memory cell arrays such as channel structures are formed, and the peripheral circuit region PR may be a region where structures related to an operation of the memory cell arrays such as a decoder, a logic circuit, and a read only memory (ROM) are formed.

The preliminary polishing stop layer 210A may be patterned to form a polishing stop layer 210. The polishing stop layers 210 may be formed on the chip regions CHR of the substrate 200. For example, the polishing stop layer 210 may be formed in the first region AR1 of the substrate 200. The polishing stop layers 210 may be arranged in the first direction I and the second direction II.

Referring to FIG. 2C, a gap fill layer 220 may be formed in the scribe lane region SR of the substrate 200. First, a preliminary gap filling layer (not shown) may be formed in openings formed by patterning the preliminary polishing stop layer 210A. Subsequently, the gap fill layers 220 may be formed by polishing the preliminary gap fill layer to expose the polishing stop layers 210. Here, the gap fill layer 220 may be formed in the second regions AR2 of the chip regions CHR. For example, the gap fill layer 220 may be formed in the second regions AR2 positioned between the first regions AR1. Here, the gap fill layer 220 may include an insulating material such as oxide.

The polishing stop layer 210 may have stress of a first type. The gap fill layer 220 may have stress of a second type different from the first type. The first type stress may be tensile stress and the second type stress may be compressive stress and vice versa. Therefore, because the polishing stop layer 210 and the gap fill layer 220 may induce or generate different types of stress in the substrate 200. An induced first type of stress may be offset by an opposing second type of stress. Accordingly, bending or deformation of the substrate 200 caused by a first type of stress may be prevented or reduced using an opposite second type of stress.

According to the manufacturing method as described above, the polishing stop layers 210 and the gap fill layers 220 having different types of stress may be formed on the substrate 200. For example, the polishing stop layer 210 having a tensile stress may be formed in the first region AR1 of the substrate 200. The gap fill layer 220 having a compressive stress may be formed in the second region AR2 of the substrate 200. It is preferable that the first and second types of stress have equal magnitudes and oppose each other by acting in opposite directions by exerting their respective opposing forces on the same geometric axis. In alternate embodiments, however, the magnitudes of opposing stresses need not be identical and need not be perfectly aligned on one geometric axis in order to at least reduce stress-induced deformation.

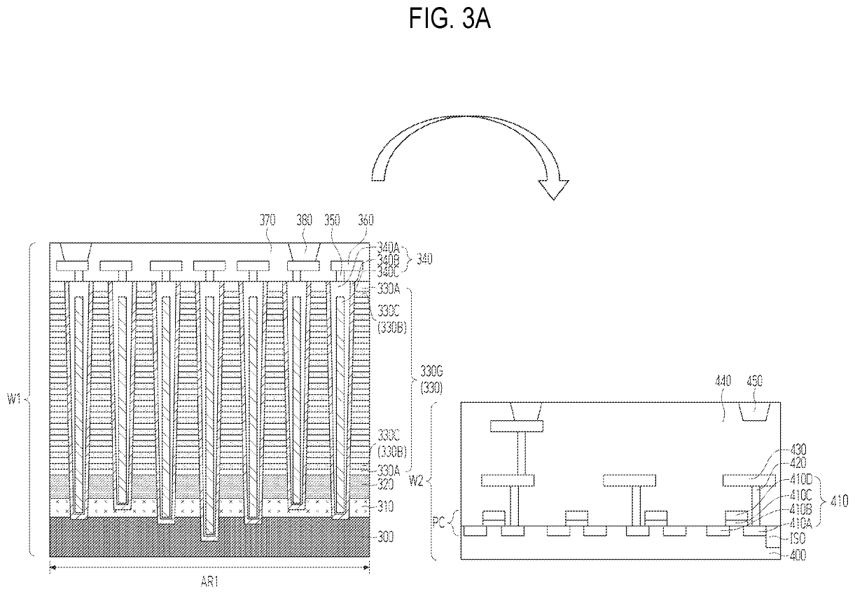

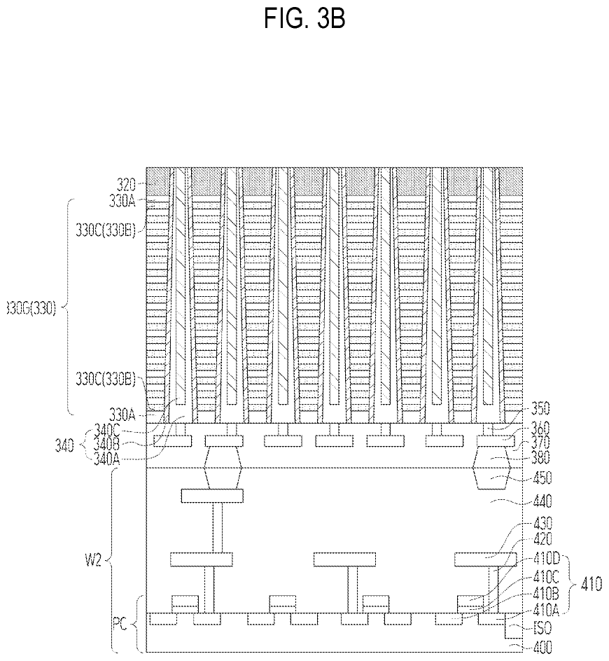

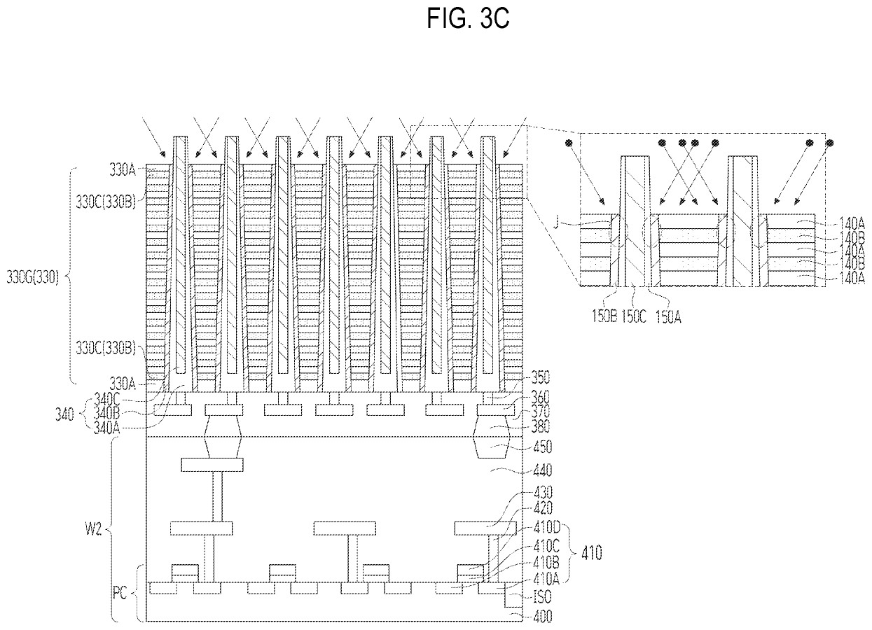

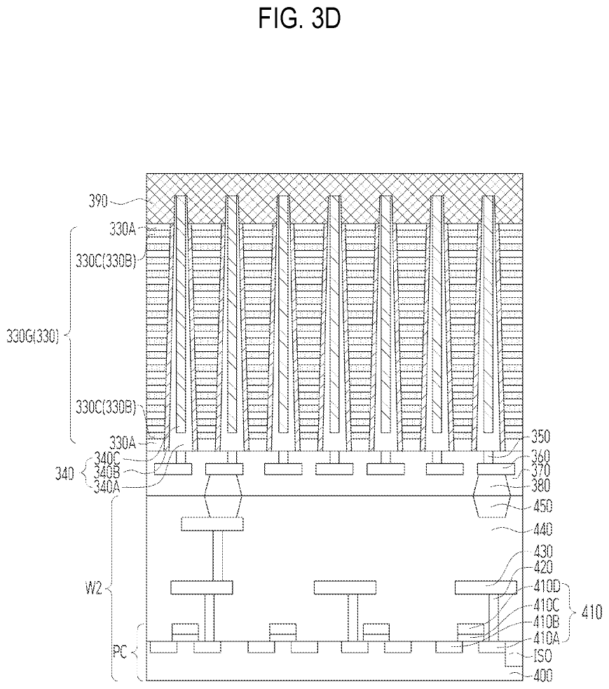

FIGS. 3A to 3D are diagrams illustrating a method of manufacturing a semiconductor device according to an embodiment of the present disclosure. Hereinafter, a content overlapping a content described above is omitted.

Referring to FIG. 3A, a first wafer W1 may be formed, separately and apart from a different second wafer W2. First, a polishing stop layer 320 may be formed on a substrate 300 of the first wafer W1. For example, and referring to FIGS. 2A to 2C again, the polishing stop layer 320 may be formed on the first region AR1 of the substrate 300. Here, the polishing stop layer 320 might not exist on the second region AR2, which is best seen in FIG. 2B. The first region AR1 may be the cell region CER, and the second region AR2 may be the peripheral circuit region PR. The polishing stop layer 320 may include a material having a selectivity to oxide. Alternatively, the polishing stop layer 320 may include at least one of nitride, tungsten, cobalt silicide, aluminum oxide, and titanium silicide. For example, the polishing stop layer 320 may include nitride.

Before forming the polishing stop layer 320, however, a buffer layer 310 may be formed. For example, referring to FIGS. 2A to 2C again, a preliminary buffer layer may be formed before forming the preliminary polishing stop layer. Subsequently, when patterning the preliminary polishing stop layer, the buffer layer may be formed by patterning the preliminary buffer layer. The buffer layer 310 may be for preventing the substrate 300 from being damaged during a process of forming channel structures 340 in a subsequent process. Here, the buffer layer 310 may include an insulating material such as oxide.

Subsequently, a stack 330 may be formed on the polished stop layer 320. For example, referring to FIGS. 2A to 2C again, the stack may be formed on the polishing stop layer and the gap fill layer. As shown in FIG. 3A, the stack 330 may include alternately stacked first material layers 330A and second material layers 330B. The first material layers 330A may include an insulating material such as oxide. The second material layers 330B may include a sacrificial material such as nitride. Alternatively, the second material layers 330B may include a conductive material such as tungsten, molybdenum, or polysilicon.

Subsequently, the channel structures 340 extending through the stack 330 and the polishing stop layer 320 may be formed. As shown in FIG. 3, the channel structures 340 may have different vertical lengths due to a manufacturing process. The channel structures 340 may thus pass through the polishing stop layer 320. At least one of the channel structures 340 may extend into the buffer layer 310. Alternatively, and as shown in FIG. 3, channel structures 340 may also extend into the substrate 300. Each of the channel structures 340 may of course include a channel layer 340A, a memory layer 340B surrounding the channel layer 340A, and an insulating core 340C in the channel layer 340A.

The channel structures 340 may be formed in the first region AR1 but might not be formed in the second region AR2. For example, the channel structures 340 may be formed in the cell region CER.

As used herein, the term “aspect ratio” refers to the ratio of a width to a height. In order to form the channel structures 340, openings extending through the stack 330 may be required to be formed, due to a process limitation. Depths of the openings may thus be different. As an aspect ratio of the stack 330 increases, such a problem may be exacerbated. Accordingly, the channel structures 340 may have different heights.

Subsequently, the second material layers 330B may be replaced with third material layers 330C through a slit (not shown). Accordingly, a gate structure 330G including alternately stacked first material layers 330A and third material layers 330C may be formed. The third material layers 330C may include a conductive material such as tungsten, molybdenum, or polysilicon. Here, the third material layers 330C may be a word line, a bit line, a drain select line, or a source select line. For reference, when the second material layers 330B include a conductive material, an alternative process may be omitted. In this case, the stack 330 may be used as the gate structure 330G. Subsequently, a slit structure (not shown) may be formed in the slit. Here, the slit structure may include an insulating material, a conductive material, a semiconductor material, or the like.

Subsequently, first contact vias 350, first lines 360, and first bonding pads 380 may be formed on the gate structure 330G. The first contact vias 350 may be connected to the channel structures 340, respectively. The first lines 360 may be connected to the first contact vias 350, respectively. At least one of the first bonding pads 380 may be connected to the first line 360. The first contact vias 350, the first lines 360, and the first bonding pads 380 may be formed in a first interlayer insulating layer 370. Accordingly, the first wafer W1 including at least one of, the substrate 300, the buffer layer 310, the polishing stop layer 320, the gate structure 330, the channel structures 340, the first contact vias 350, the first lines 360, the first interlayer insulating layer 370, and the first bonding pads 380 may be formed.

A second wafer W2 may be formed. First, the peripheral circuit PC may be formed. The peripheral circuit PC may be formed on a substrate 400. The peripheral circuit PC may include a transistor 410. The transistor 410 may include at least one of junctions 410A and 410B, a gate insulating layer 410C, and a gate electrode 410D. An isolation insulating layer ISO may be formed in the substrate 400, and an active region of the transistor 410 may be defined by the isolation insulating layer ISO. Subsequently, second contact vias 420 and second lines 430 may be formed on the peripheral circuit PC. At least one of the second contact vias 420 may be connected to the transistor 410. The second lines 430 may be connected to the second contact vias 420, respectively. Subsequently, second bonding pads 450 may be formed. The second bonding pads 450 may be connected to at least one of the second lines 430. The second contact vias 420, the second lines 430, and the second bonding pads 450 may be formed in the second interlayer insulating layer 440.

Subsequently, the first wafer W1 and the second wafer W2 may be bonded. For example, an upper surface of the first wafer W1 and an upper surface of the second wafer W2 may be bonded. The first bonding pads 380 of the first wafer W1 and the second bonding pads 450 of the second wafer W2 may be bonded. The first wafer W1 may be rotated and bonded to the second wafer W2.

Referring to FIG. 3B, which shows the first and second wafers W1 and W2 joined by bonding, the substrate 300 and the buffer layer 310 may be polished to remove and thus expose the polishing stop layer 320. For example, the substrate 300 and the channel structures 340 may be polished to remove and thus expose the polishing stop layer 320. For reference, only a portion of the polishing stop layer 320 may also be removed. Because the channel structures 340 may extend into the buffer layer 310 or the substrate 300 by passing through the polishing stop layer 320, an upper surface of the polishing stop layer 320 and an upper surface of the channel structures 340 may be positioned at substantially the same level by polishing the channel structures 340. In other words, the channel structures 340 may be polished so that the channel structures 340 have substantially the same height.

Referring to FIG. 3C, the polishing stop layer 320 may be removed. In this case, a sidewall of the channel structures 340 may be exposed. For example, the memory layers 340B of the channel structures 340 may be exposed. Subsequently, a portion of the memory layers 340B may be removed to expose a sidewall of the channel layers 340A. Subsequently, the junction J may be formed in the channel layer 340A positioned at a level corresponding to the third material layers 330C. For example, the junctions J may be formed in the channel layers 340A by doping with an impurity. Because the channel structures 340 have substantially the same height, the junctions J may also be formed at substantially the same level. Accordingly, the memory cells may have a uniform characteristic. Here, the third material layers 330C may be a source select line.

Referring to FIG. 3D, a source structure 390 may be formed on the gate structure 330G. For example, the source structure 390 connected to the channel structures 340 may be formed. Here, the channel layer 340A may be connected to the source structure 390.

According to the manufacturing method as described above, even though the heights of the channel structures 340 are formed to be different before bonding, after bonding, the heights may become substantially the same by polishing the channel structures 340 using the polishing stop layer 320. Accordingly, the junctions J may be formed at substantially the same level in the channel structures 340, and the memory cells may have a uniform characteristic.

The peripheral circuit PC may be configured as the separate second wafer W2 and bonded to the first wafer W1, which is configured to be a memory cell array including the channel structures 340. Therefore, by configuring a peripheral circuit PC to be related to the operation of the memory cell array as the separate second wafer W2, more memory cells may be formed in the first wafer W1 including the memory cell array, and thus more data may be stored therein and usable by the peripheral circuit PC in the second wafer W2.

Although embodiments according to the technical spirit of the present disclosure have been described with reference to the accompanying drawings, this is only for describing an embodiment according to the concept of the present disclosure, and the present disclosure is not limited to the above-described embodiments. Within the scope of the technical spirit of the present disclosure described in the claims, various forms of substitution, modification, and change of the embodiments will be possible by those skilled in the art to which the present disclosure belongs, and these also belong to the scope of the present disclosure.

What is claimed is:

1. A method of manufacturing a semiconductor device, the method comprising:
forming a polishing stop layer on a substrate;
forming a stack on the polishing stop layer;
forming channel structures extending through the stack and the polishing stop layer extending into the substrate, wherein at least two channel structures among the channel structures have different heights;
polishing the substrate and the channel structures to expose the polishing stop layer; and
removing the polishing stop layer.

2. The method of claim 1, wherein polishing the substrate and the channel structures comprises polishing the channel structures so that the channel structures have substantially the same height.

3. The method of claim 1, further comprising:
forming a source structure connected to the channel structures on the stack after removing the polishing stop layer.

4. The method of claim 1, wherein the substrate includes a first region and a second region, the polishing stop layer is formed in the first region, and a gap fill layer is formed in the second region.

5. The method of claim 4, wherein the polishing stop layer has stress of a first type, and the gap fill layer has stress of a second type, the first and second types of stress being different from each other.

6. The method of claim 5, wherein the first type stress is tensile stress, and the second type stress is compressive stress.

7. The method of claim 4, wherein the first region is a cell region, and the second region is a peripheral circuit region.

8. The method of claim 7, wherein the channel structures are formed in the cell region.

9. The method of claim 4, wherein the polishing stop layer includes a material having a selectivity to oxide, and the gap fill layer comprises an oxide.

10. The method of claim 1, wherein the polishing stop layer comprises at least one of nitride, tungsten, cobalt silicide, aluminum oxide, and titanium silicide.

11. The method of claim 1, further comprising:
forming a buffer layer before forming the polishing stop layer.

12. A method of manufacturing a semiconductor device, the method comprising:
forming a substrate including a first region and a second region;
forming a polishing stop layer having stress of a first type in the first region of the substrate;
forming a gap fill layer having stress of a second type different from the first type in the second region of the substrate;
forming a stack on the polishing stop layer and the gap fill layer;
forming channel structures extending through the stack and the polishing stop layer and having different heights; and
polishing the substrate and the channel structures to expose the polishing stop layer.

13. The method of claim 12, wherein the first type stress is tensile stress, and the second type stress is compressive stress.

14. The method of claim 12, further comprising:
removing the polishing stop layer; and
forming a source structure connected to the channel structures on the stack.

15. The method of claim 12, wherein polishing the substrate and the channel structures comprises polishing the channel structures so that the channel structures have substantially the same height.

16. The method of claim 12, wherein the first region is a cell region, and the second region is a peripheral circuit region.

17. The method of claim 16, wherein the channel structures are formed in the cell region.

18. The method of claim 12, wherein the polishing stop layer includes a material having a selectivity to oxide, and the gap fill layer includes oxide.

19. The method of claim 12, wherein the polishing stop layer includes at least one of nitride, tungsten, cobalt silicide, aluminum oxide, and titanium silicide.

20. The method of claim 12, further comprising:
forming a buffer layer before forming the polishing stop layer.

21. A method of manufacturing a semiconductor device, the method comprising:
forming a buffer layer;
forming a polishing stop layer on the buffer layer;
forming a stack on the polishing stop layer;
forming channel structures extending into the buffer layer through the stack and the polishing stop layer;
polishing the buffer layer and the channel structures to expose the polishing stop layer; and
removing the polishing stop layer.

22. The method of claim 21, further comprising:
forming a source structure connected to the channel structures on the stack after removing the polishing stop layer.

23. The method of claim 21, wherein the polishing the buffer layer and the channel structures comprises polishing the channel structures so that the channel structures have substantially the same height.

24. The method of claim 21, wherein the polishing stop layer includes a material having a selectivity to oxide.

25. The method of claim 21, wherein the polishing stop layer includes at least one of nitride, tungsten, cobalt silicide, aluminum oxide, and titanium silicide.
